(19) United States
(12) Patent Application Publication
(10) Pub. No.: US 2022/0347986 A1
(43) Pub. Date: Nov. 3, 2022

(54) MULTILAYERED CUSHION PAD AND METHOD FOR MANUFACTURING THE SAME

(71) Applicant: NAN YA PLASTICS CORPORATION, TAIPEI (TW)

(72) Inventors: TE-CHAO LIAO, TAIPEI (TW); CHUN-CHE TSAO, TAIPEI (TW); SHIH-HSUN YEN, TAIPEI (TW)

(21) Appl. No.: 17/546,052

(22) Filed: Dec. 9, 2021

(30) Foreign Application Priority Data
Apr. 30, 2021 (TW) 110115702

(51) Int. Cl. B32B 27/12; B32B 37/04; B32B 37/10; B32B 37/06; B32B 37/18; B32B 5/02

(52) U.S. Cl. CPC B32B 27/12; B32B 37/04; B32B 37/10; B32B 37/06; B32B 37/182; B32B 5/024; B32B 2262/0269; B32B 2305/188; B32B 2307/54; B32B 2307/536

(57) ABSTRACT

A multilayered cushion pad and a method for manufacturing the same are provided. The multilayered cushion pad includes a first woven fabric, a second woven fabric, and a first buffering layer. The first buffering layer is disposed between the first woven fabric and the second woven fabric. A material of the first woven fabric includes a poly-p-phenylene benzobisoxazole fiber, and a material of the second woven fabric is selected from the group consisting of: a poly-p-phenylene benzobisoxazole fiber, a polyphenylene sulfide fiber, a polybenzimidazole fiber, a ceramic fiber, a basalt fiber, an alkaline metal fiber, a silicic acid fiber, and a combination thereof. A material of the first buffering layer is selected from the group consisting of: a silicone rubber resin, a fluororubber resin, a polyvinylidene difluoride resin, a polyetheretherketone resin, a polyimide resin, a polyamide-imide resin, and a combination thereof.

### CROSS-REFERENCE TO RELATED PATENT APPLICATION

This application claims the benefit of priority to Taiwan Patent Application No. 110115702, filed on Apr. 30, 2021. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a cushion pad and a method for manufacturing the same, and more particularly to a multilayered cushion pad and a method for manufacturing the same.

### BACKGROUND OF THE DISCLOSURE

A copper clad laminate is an essential material in the electronics industry. The copper clad laminate is usually used to manufacture a printed circuit board, so as to enable circuits in electronic products to be electrically conducted with each other for circuit integration. Hot-pressing is a necessary step for manufacturing the copper clad laminate. When a substrate is hot-pressed, two cushion pads are respectively disposed on two opposite surfaces of the substrate, so that the substrate can be uniformly hot-pressed via the two cushion pads (that is, energy and pressure are uniformly applied to the substrate).

A material commonly used for the cushion pads is a kraft paper, an organic fiber, or an inorganic fiber. The cushion pad with a specific thickness can be formed by adhering the organic fiber or the inorganic fiber via glue or through a weaving technology. Such a cushion pad has an adequate mechanical strength and can be reused.

With the development of 5^{th} generation wireless system (5G), the substrate for 5G transmissions requires low dielectric properties, a thin thickness, and functional properties. Further, a hot-pressing temperature required for manufacturing the copper clad laminate is increased from the original 230° C. to 400° C. However, the conventional cushion pad cannot endure the new hot-pressing temperature. The conventional cushion pad will be thermally degraded at such a high temperature (400° C.), thereby resulting in poor physical properties. After measurement, the conventional cushion pad can only be used about 50 times when the hot-pressing temperature is 400° C. Therefore, there is still a need in the related art for an improved cushion pad that can endure a higher hot-pressing temperature.

### SUMMARY OF THE DISCLOSURE

In response to the above-referenced technical inadequacy, the present disclosure provides a multilayered cushion pad and a method for manufacturing the same.

In one aspect, the present disclosure provides a multilayered cushion pad. The multilayered cushion pad includes a first woven fabric, a second woven fabric, and a first buffering layer. A material of the first woven fabric includes a poly-p-phenylene benzobisoxazole fiber. The second woven fabric is disposed on the first woven fabric. A material of the second woven fabric is selected from the group consisting of: a poly-p-phenylene benzobisoxazole fiber, a polyphenylene sulfide fiber, a polybenzimidazole fiber, a ceramic fiber, a basalt fiber, an alkaline metal fiber, a silicic acid fiber, and a combination thereof. The first buffering layer is disposed between the first woven fabric and the second woven fabric. A material of the first buffering layer is selected from the group consisting of: a silicone rubber resin, a fluororubber resin, a polyvinylidene difluoride resin, a polyetheretherketone resin, a polyimide resin, a polyamide-imide resin, and a combination thereof.

In certain embodiments, a part of the first woven fabric is overlapped with one part of the first buffering layer to form a first interface layer, and a part of the second woven fabric is overlapped with another part of the first buffering layer to form a second interface layer.

In certain embodiments, a thickness of the first interface layer ranges from 0.03 mm to 1.2 mm, and a thickness of the second interface layer ranges from 0.03 mm to 1.2 mm.

In certain embodiments, a basis weight of the first woven fabric ranges from 250 g/cm² to 800 g/cm², and a basis weight of the second woven fabric ranges from 250 g/cm² to 800 g/cm².

In certain embodiments, a basis weight of the multilayered cushion pad ranges from 1200 g/cm² to 1800 g/cm².

In certain embodiments, a total thickness of the multilayered cushion pad ranges from 25 mm to 45 mm.

In certain embodiments, a Shore hardness of the multilayered cushion pad ranges from 45 to 100.

In certain embodiments, a mechanical strength of the multilayered cushion pad ranges from 18 MPa to 30 MPa.

In certain embodiments, when the multilayered cushion pad is disposed between a lower plate with a temperature of 30° C. and an upper plate with a temperature of 300° C., a heating rate of the multilayered cushion pad ranges from 15° C./minute to 25° C./minute.

In certain embodiments, the multilayered cushion pad further includes a third woven fabric and a second buffering layer. The third woven fabric is disposed on the second woven fabric. A material of the third woven fabric is selected from the group consisting of: a poly-p-phenylene benzobisoxazole fiber, a polyphenylene sulfide fiber, a polybenzimidazole fiber, a ceramic fiber, a basalt fiber, an alkaline metal fiber, a silicic acid fiber, and a combination thereof. The second buffering layer is disposed between the second woven fabric and the third woven fabric. A material of the second buffering layer is selected from the group consisting of: a silicone rubber resin, a fluororubber resin, a polyvinylidene difluoride resin, a polyetheretherketone resin, a polyimide resin, a polyamide-imide resin, and a combination thereof.

In another aspect, the present disclosure provides a method for manufacturing the multilayered cushion pad, which includes steps as follows. A first woven fabric and a second woven fabric are provided. A material of the first woven fabric includes a poly-p-phenylene benzobisoxazole fiber, and a material of the second woven fabric is selected from the group consisting of: a poly-p-phenylene benzobisoxazole fiber, a polyphenylene sulfide fiber, a polybenzimidazole fiber, a ceramic fiber, a basalt fiber, an alkaline metal fiber, a silicic acid fiber, and a combination thereof. A first buffering resin is applied between the first woven fabric and the second woven fabric to form a laminated structure. The first buffering resin is selected from the group consisting of: a silicone rubber resin, a fluororubber resin, a polyvinylidene difluoride resin, a polyetheretherketone resin, a polyimide resin, a polyamide-imide resin, and a combination thereof. The laminated structure is hot-pressed so that the first buffering resin is formed as a first buffering layer between the first woven fabric and the second woven fabric.

In certain embodiments, in the step of hot-pressing the laminated structure, one part of the first buffering resin permeates into the first woven fabric and forms as a first interface layer between the first woven fabric and the first buffering layer. Another part of the first buffering resin permeates into the second woven fabric and forms as a second interface layer between the second woven fabric and the first buffering layer.

Therefore, in the multilayered cushion pad and the method for manufacturing the same provided by the present disclosure, by virtue of “the material of the first woven fabric including a poly-p-phenylene benzobisoxazole fiber” and “the first buffering layer being disposed between the first woven fabric and the second woven fabric”, the multilayered cushion pad can have an improved endurance against high temperature.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a multilayered cushion pad according to a first embodiment of the present disclosure;

FIG. 2 shows an enlarged view of part II of FIG. 1;

FIG. 3 is a schematic side view of the multilayered cushion pad according to a second embodiment of the present disclosure;

FIG. 4 is a flowchart of a method for manufacturing the multilayered cushion pad according to the first embodiment of the present disclosure; and

FIG. 5 is a flowchart of the method for manufacturing the multilayered cushion pad according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

In order to improve thermal endurance of a conventional cushion pad, a high temperature resistant fiber is used to form a woven fabric, and a high temperature resistant resin is used to form a buffering layer in the present disclosure. A multilayered cushion pad of the present disclosure is formed by alternately stacking the woven fabric and the buffering layer. Compared to the conventional cushion pad made from a unitary component, the multilayered cushion pad of the present disclosure can be hot-pressed more than 100 times at a temperature of 400° C.

### First Embodiment

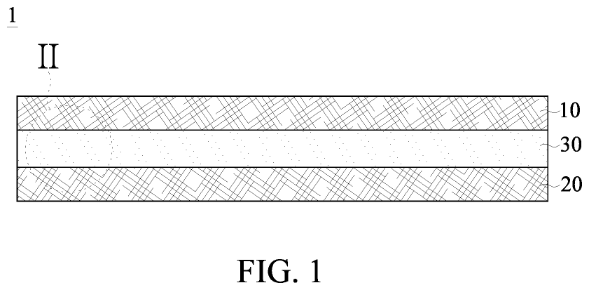

Referring to FIG. 1, FIG. 1 is a schematic side view of a multilayered cushion pad according to a first embodiment of the present disclosure. In the first embodiment, a multilayered cushion pad 1 is a three-layered structure. The multilayered cushion pad 1 includes a first woven fabric 10, a second woven fabric 20, and a first buffering layer 30. The first buffering layer 30 is disposed between the first woven fabric 10 and the second woven fabric 20.

The first woven fabric 10 is formed from a high temperature resistant fiber through a weaving technology. The high temperature resistant fiber has a continuous use temperature (CUT) of higher than 300° C., so that the multilayered cushion pad 1 can be applied to a hot-pressing temperature of higher than 400° C. In other words, the high temperature resistant fiber can be safely subjected to a temperature of higher than 300° C. for a long period of time, without undergoing degradation, oxidation, a cross-linking reaction or a hydrolysis reaction. Specifically, a material of the first woven fabric 10 includes a poly-p-phenylene benzobisoxazole (PBO) fiber (the CUT: 350° C.).

The second woven fabric 20 is also formed from a high temperature resistant fiber through the weaving technology. The high temperature resistant fiber can be classified into an organic fiber or an inorganic fiber. Specifically, the organic fiber can be a poly-p-phenylene benzobisoxazole fiber, a polyphenylene sulfide (PPS) fiber (the CUT: 550° C.), or a polybenzimidazole (PBI) fiber (the CUT: 345° C.). The inorganic fiber can be a ceramic fiber, a basalt fiber, an alkaline metal fiber, or a silicic acid fiber.

In other words, a material of the second woven fabric 20 is selected from the group consisting of: a poly-p-phenylene benzobisoxazole fiber, a polyphenylene sulfide fiber, a polybenzimidazole fiber, a ceramic fiber, a basalt fiber, an alkaline metal fiber, a silicic acid fiber, and a combination thereof.

In the first embodiment, the material of the first woven fabric 10 and the material of the second woven fabric 20 can be the same or different. For the convenience of manufacturing, the material of the first woven fabric 10 and the material of the second woven fabric 20 can be the same. Or, according to property requirements of the multilayered cushion pad 1, the first woven fabric 10 and the second woven fabric 20 can be formed from different high temperature resistant fibers, so that two sides of the multilayered cushion pad 1 are formed from different materials.

In addition, there are no restrictions on the weaving technology through which the first woven fabric 10 and the second woven fabric 20 are formed, and parameters used in the weaving technology are also not restricted. For example, a needle diameter, a frequency for punching the needle, and a depth for punching the needle can be adjusted, so that the manufactured multilayered cushion pad 1 can have a desired mechanical strength and a desired thickness. It should be noted that no matter how the parameters used in the weaving technology are adjusted, the multilayered cushion pad 1 of the present disclosure can endure a high hot-pressing temperature (400° C.) and have a long service life. Therefore, the parameters used in the weaving technology are only provided for illustrative purposes, but not to limit the scope of the multilayered cushion pad 1 of the present disclosure. After measurement, it can be observed that the multilayered cushion pad 1 can have a stronger mechanical strength and a thicker thickness when a larger needle diameter, a higher frequency for punching the needle, or a deeper depth for punching the needle is used.

In the present disclosure, a basis weight of the first woven fabric 10 ranges from 250 g/cm² to 800 g/cm². A basis weight of the second woven fabric 20 ranges from 250 g/cm² to 800 g/cm². However, the present disclosure is not limited thereto. The basis weight is a unit for expressing a weight of paper, and a common unit of the basis weight is gram per square meter (g/m²). In the present disclosure, the unit of the basis weight is gram per square centimeter (g/cm²), so as to define a weight of layers (the first woven fabric 10 and the second woven fabric 20) on unit area.

The first buffering layer 30 is disposed between the first woven fabric 10 and the second woven fabric 20, so that the multilayered cushion pad 1 can have high temperature endurance and a good buffering effect. The first buffering layer 30 is formed from a high temperature resistant resin by solidification. The high temperature resistant resin is selected from the group consisting of: a silicone rubber resin, a fluororubber resin, a polyvinylidene difluoride (PVDF) resin, a polyetheretherketone (PEEK) resin, a polyimide (PI) resin, a polyamide-imide (PAI) resin, and a combination thereof.

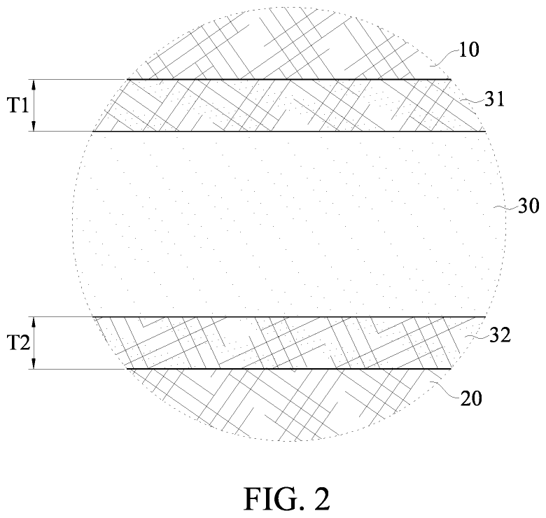

In the first embodiment, the first buffering layer 30 further includes a first interface layer 31 and a second interface layer 32. The formation of the first interface layer 31 and the second interface layer 32 can strengthen adhesive forces between the first woven fabric 10, the second woven fabric 20, and the first buffering layer 30, and can enhance a thermal conductivity of the multilayered cushion pad 1. Referring to FIG. 2, FIG. 2 shows an enlarged view of part II of FIG. 1. The first interface layer 31 is formed between the first woven fabric 10 and the first buffering layer 30. The first interface layer 31 includes the material of the first woven fabric 10 and the material of the first buffering layer 30. The second interface layer 32 is formed between the first buffering layer 30 and the second woven fabric 20. The second interface layer 32 includes the material of the second woven fabric 20 and the material of the first buffering layer 30. Specifically, a thickness T1 of the first interface layer 31 ranges from 0.03 mm to 1.2 mm. A thickness T2 of the second interface layer 32 ranges from 0.03 mm to 1.2 mm. A basis weight of the multilayered cushion pad 1 ranges from 1200 g/cm² to 1800 g/cm². However, the present disclosure is not limited thereto.

In the first embodiment, a thickness of the woven fabric (the first woven fabric 10 and the second woven fabric 20) can be larger than, equal to, or smaller than a thickness of the buffering layer (the first buffering layer 30) according to different requirements, and is not limited thereto. In the first embodiment, a total thickness of the multilayered cushion pad 1 ranges from 25 mm to 45 mm, such that a buffering property and the thermal conductivity of the multilayered cushion pad 1 are adequate. However, the aforementioned description is merely an example and is not meant to limit the scope of the present disclosure.

### Second Embodiment

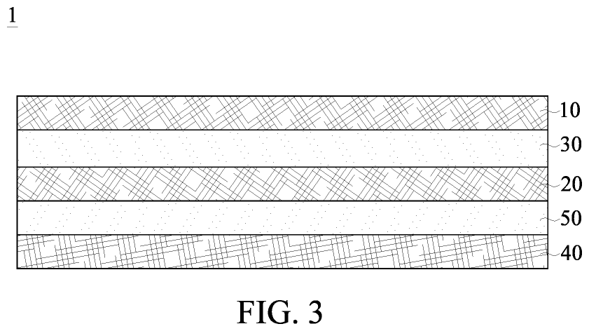

Referring to FIG. 3, FIG. 3 is a schematic side view of the multilayered cushion pad according to a second embodiment of the present disclosure. The multilayered cushion pad 1 in the second embodiment is similar to the multilayered cushion pad 1 in the first embodiment. The difference is that the multilayered cushion pad 1 in the second embodiment is a five-layered structure. In addition to the first woven fabric 10, the second woven fabric 20, the first buffering layer 30, the multilayered cushion pad 1 in the second embodiment further includes a third woven fabric 40 and a second buffering layer 50. The third woven fabric 40 is disposed on the second woven fabric 20. The second buffering layer 50 is disposed between the second woven fabric 20, and the third woven fabric 40.

A material of the third woven fabric 40 can be the same or different from the material of the second woven fabric 20 mentioned previously. In other words, the material of the third woven fabric 40 can be selected from the group consisting of: a poly-p-phenylene benzobisoxazole fiber, a polyphenylene sulfide fiber, a polybenzimidazole fiber, a ceramic fiber, a basalt fiber, an alkaline metal fiber, a silicic acid fiber, and a combination thereof.

A material of the second buffering layer 50 can be the same or different from the material of the first buffering layer 30. In other words, the material of the second buffering layer 50 can be selected from the group consisting of: a silicone rubber resin, a fluororubber resin, a polyvinylidene difluoride resin, a polyetheretherketone resin, a polyimide resin, a polyamide-imide resin, and a combination thereof.

In the second embodiment, the aforesaid interface layers (the first interface layer 31 and the second interface layer 32) can also be formed between the woven fabric (the first woven fabric 10, the second woven fabric 20, and the third woven fabric 40) and the buffering layer (the first buffering layer 30 and the second buffering layer 50), such that the buffering property and the thermal conductivity of the multilayered cushion pad 1 can be enhanced. The structure and the property of the interface layers (the first interface layer 31 and the second interface layer 32) have been illustrated in the first embodiment, and will not be reiterated herein.

In the second embodiment, a thickness of the woven fabric (the first woven fabric 10, the second woven fabric 20, and the third woven fabric 40) can be larger than, equal to, or smaller than a thickness of the buffering layer (the first buffering layer 30 and the second buffering layer 50) according to different requirements, and is not limited thereto. In the second embodiment, a total thickness of the multilayered cushion pad 1 ranges from 25 mm to 45 mm, such that the buffering property and the thermal conductivity of the multilayered cushion pad 1 are adequate. However, the aforementioned description is merely an example and is not meant to limit the scope of the present disclosure.

### Third Embodiment

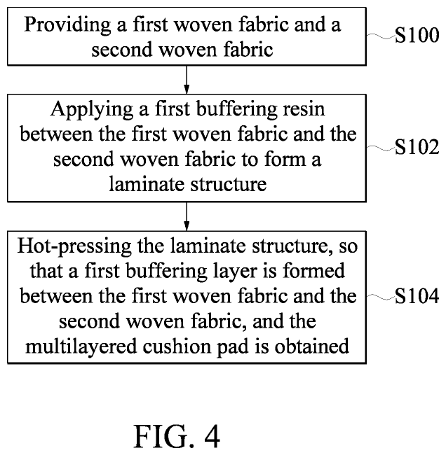

Referring to FIG. 4, FIG. 4 is a flowchart of a method for manufacturing the multilayered cushion pad according to the first embodiment of the present disclosure. The method for manufacturing the multilayered cushion pad 1 (the three-layered structure) according to the first embodiment includes steps as follows.

The first woven fabric 10 and the second woven fabric 20 are provided (step S100). The material of the first woven fabric 10 includes a poly-p-phenylene benzobisoxazole fiber. The material of the second woven fabric 20 is selected from the group consisting of: a poly-p-phenylene benzobisoxazole fiber, a polyphenylene sulfide fiber, a polybenzimidazole fiber, a ceramic fiber, a basalt fiber, an alkaline metal fiber, a silicic acid fiber, and a combination thereof. Subsequently, a first buffering resin is applied between the first woven fabric 10 and the second woven fabric 20 to form a laminate structure (step S102). The first buffering resin is selected from the group consisting of: a silicone rubber resin, a fluororubber resin, a polyvinylidene difluoride resin, a polyetheretherketone resin, a polyimide resin, a polyamide-imide resin, and a combination thereof. Then, the laminate structure in step S102 is hot-pressed, so that the first buffering layer 30 is formed between the first woven fabric 10 and the second woven fabric 20, and the multilayered cushion pad 1 is obtained (step S104).

Specifically, in the hot-pressing step, a part of the first buffering resin permeates into fibers of the first woven fabric 10. After the first buffering resin is solidified, the first interface layer 31 is formed between the first woven fabric 10 and the first buffering layer 30. Accordingly, the first woven fabric 10 and the first buffering layer 30 can be tightly connected with each other. Similarly, another part of the first buffering resin permeates into fibers of the second woven fabric 20. After the first buffering resin is solidified, the second interface layer 32 is formed between the second woven fabric 20 and the first buffering layer 30. Accordingly, the second woven fabric 20 and the first buffering layer 30 can be tightly connected with each other. When the first woven fabric 10, the second woven fabric 20, and the first buffering layer 30 are tightly connected with each other, the multilayered cushion pad 1 can have a good thermal conductivity. However, the aforementioned description is merely an example and is not meant to limit the scope of the present disclosure.

### Fourth Embodiment

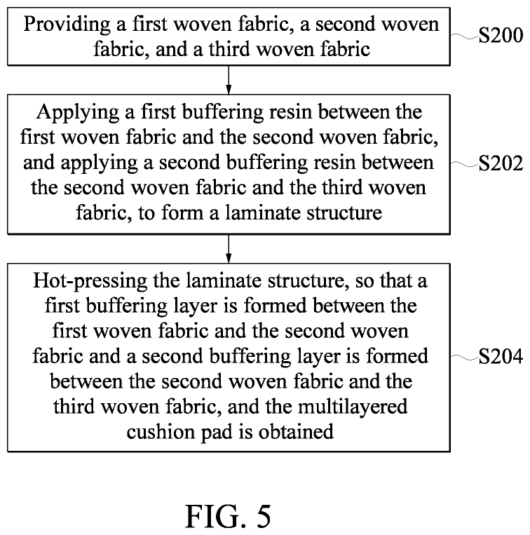

Referring to FIG. 5, FIG. 5 is a flowchart of the method for manufacturing the multilayered cushion pad according to the second embodiment of the present disclosure. The method for manufacturing the multilayered cushion pad 1 (the five-layered structure) according to the second embodiment includes steps as follows.

The first woven fabric 10, the second woven fabric 20, and the third woven fabric 40 are provided (step S200). The material of the first woven fabric 10 includes a poly-p-phenylene benzobisoxazole fiber. The material of each of the second woven fabric 20 and the third woven fabric 40 is independently selected from the group consisting of: a poly-p-phenylene benzobisoxazole fiber, a polyphenylene sulfide fiber, a polybenzimidazole fiber, a ceramic fiber, a basalt fiber, an alkaline metal fiber, a silicic acid fiber, and a combination thereof. Subsequently, a first buffering resin is applied between the first woven fabric 10 and the second woven fabric 20, and a second buffering resin is applied between the second woven fabric 20 and the third woven fabric 40, so as to form a laminate structure (step S202). The first buffering resin and the second buffering resin are each independently selected from the group consisting of: a silicone rubber resin, a fluororubber resin, a polyvinylidene difluoride resin, a polyetheretherketone resin, a polyimide resin, a polyamide-imide resin, and a combination thereof. Then, the laminate structure in step S202 is hot-pressed, so that the first buffering layer 30 is formed between the first woven fabric 10 and the second woven fabric 20, the second buffering layer 50 is formed between the second woven fabric 20 and the third woven fabric 40, and the multilayered cushion pad 1 is obtained (step S204).

To prove that the multilayered cushion pad 1 of the present disclosure can endure a high hot-pressing temperature and has a good thermal conductivity, different ones of the multilayered cushion pad 1 are prepared in the present disclosure. Specific components and preparing conditions of the different ones of the multilayered cushion pad 1 are listed in Table 1. Properties of the different ones of the multilayered cushion pad 1 (such as a heating rate, a hot-pressing usage count, a Shore hardness, and the mechanical strength) are measured and listed in Table 2.

The heating rate of the multilayered cushion pad 1 is measured by a thermocouple. When simulating a hot-pressing process, temperatures of two clamping plates are respectively set at 400° C. (an upper plate) and 30° C. (a lower plate), and a pressure applied by the clamping plates is 25 kg/cm². The hot-pressing process lasts for 30 minutes. In addition, the hot-pressing usage count is also calculated under this condition. The Shore hardness of the multilayered cushion pad 1 is measured by a hardness tester. The multilayered cushion pad 1 is cut into a rectangular sample with a size of 100 mm×50 mm. A nick is formed at a center of a short side of the sample, and the nick extends along a length direction of the sample for 5 mm. Two opposite ends of the short side of the sample are clipped on a tensile testing machine. Subsequently, with a velocity of 300 mm/min, the sample is stretched to the extent of being fractured. During the stretching, a highest pressure is recorded, and is taken as the mechanical strength.

TABLE 1
components and preparing conditions of the multilayered cushion
pad in Examples 1 to 3 and Comparative Examples 1 to 3.

| | | Examples | | | Comparative Examples | | |
|---|---|---|---|---|---|---|---|
| | | 1 | 2 | 3 | 1 | 2 | 3 |
| First woven | Material | PBO | PBO | PBO | Ceramic | Basalt | Metal |
| fabric | | fiber | fiber | fiber | fiber | fiber | fiber |
| | Basis weight | 600 | 400 | 300 | 1000 | 900 | 1200 |
| | (g/cm²) | | | | | | |
| | Thickness (mm) | 0.8 | 0.5 | 0.3 | 1 | 0.8 | 1 |
| Second woven | Material | PBO | PBI | Silicic | Basalt | Metal | — |
| fabric | | fiber | fiber | acid fiber | fiber | fiber | |
| | Basis weight | 600 | 500 | 600 | 900 | 1200 | 0 |
| | (g/cm²) | | | | | | |
| | Thickness (mm) | 0.8 | 0.5 | 0.6 | 0.8 | 1 | 0 |
| Third woven | Material | — | PBI fiber | Metal | — | Silicic acid | Metal |
| fabric | | | | fiber | | fiber | fiber |
| | Basis weight | 0 | 500 | 200 | 0 | 900 | 1200 |
| | (g/cm²) | | | | | | |
| | Thickness (mm) | 0 | 0.3 | 0.15 | 0 | 0.8 | 1 |
| First | Material | PEEK | Fluororubber | Silicone | Silicone | Fluororubber | PEEK |
| buffering | | resin | resin | rubber resin | rubber resin | resin | resin |
| layer | Thickness (mm) | 1 | 1 | 1 | 2 | 1 | 1 |
| First interface | Thickness (mm) | 0.05 | 0.5 | 0.8 | 1.6 | 0.5 | 0.05 |
| layer | | | | | | | |
| Second interface | Thickness (mm) | 0.05 | 0.5 | 0.8 | 1.6 | 0.5 | 0.05 |
| layer | | | | | | | |
| Second | Material | PEEK | Fluororubber | Silicone | Silicone | Fluororubber | PEEK |
| buffering | | resin | resin | rubber resin | rubber resin | resin | resin |
| layer | Thickness (mm) | 1 | 1 | 1 | 2 | 1 | 0.5 |
| Hot-pressing | Temperature (° C.) | 400 | 400 | 400 | 400 | 400 | 400 |
| condition | Pressure (kg/m²) | 25 | 25 | 25 | 25 | 25 | 25 |
| Multilayered | Basis weight | 1600 | 1700 | 1400 | 1500 | 1400 | 1700 |
| cushion pad | (g/cm²) | | | | | | |
| | Thickness (mm) | 36 | 33 | 30.5 | 40 | 46 | 34 |

TABLE 2
properties of the multilayered cushion pad in Examples
1 to 3 and Comparative Examples 1 to 3.

| | Examples | | | Comparative Examples | | |
|---|---|---|---|---|---|---|
| | 1 | 2 | 3 | 1 | 2 | 3 |
| Hot-pressing | 120 | 110 | 105 | 40 | 45 | 70 |
| usage count | | | | | | |
| Heating | 20 | 16 | 22 | 15 | 12 | 30 |
| rate (° C./min) | | | | | | |
| Shore hardness | 75 | 60 | 50 | 65 | 80 | 55 |
| Mechanical | 25 | 20 | 23 | 4 | 10 | 15 |
| strength (MPa) | | | | | | |

According to the results above, the multilayered cushion pad 1 of the present disclosure can endure a higher hot-pressing temperature. Compared to those in the Comparative Examples, the multilayered cushion pad 1 of the present disclosure has a higher hot-pressing usage count and a longer service life. Further, the multilayered cushion pad 1 of the present disclosure has an adequate heating rate, Shore hardness, and mechanical strength, and can meet requirements of a hot-pressing cushion pad on the market.

### Beneficial Effects of the Embodiments

In conclusion, in the multilayered cushion pad and the method for manufacturing the same provided by the present disclosure, by virtue of “the material of the first woven fabric 10 including a poly-p-phenylene benzobisoxazole fiber” and “the first buffering layer 30 being disposed between the first woven fabric 10 and the second woven fabric 20”, the multilayered cushion pad 1 can have an improved endurance against high temperature.

Further, by virtue of “the first interface layer 31 being deposed between the first woven fabric 10 and the first buffering layer 30” and “the second interface layer 32 being deposed between the second woven fabric 20 and the first buffering layer 30”, the first woven fabric 10, the second woven fabric 20, and the first buffering layer 30 can be tightly connected with each other, so as to enhance the heating rate of the multilayered cushion pad 1.

Further, by virtue of “the basis weight of the multilayered cushion pad 1 ranging from 1200 g/cm² to 1600 g/cm²”, the multilayered cushion pad 1 can have a better durability and buffering property.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A multilayered cushion pad, comprising:
a first woven fabric, a material of the first woven fabric including a poly-p-phenylene benzobisoxazole fiber;
a second woven fabric disposed on the first woven fabric, a material of the second woven fabric being selected from the group consisting of: a poly-p-phenylene benzobisoxazole fiber, a polyphenylene sulfide fiber, a polybenzimidazole fiber, a ceramic fiber, a basalt fiber, an alkaline metal fiber, a silicic acid fiber, and a combination thereof; and
a first buffering layer disposed between the first woven fabric and the second woven fabric, a material of the first buffering layer being selected from the group consisting of: a silicone rubber resin, a fluororubber resin, a polyvinylidene difluoride resin, a polyetheretherketone resin, a polyimide resin, a polyamide-imide resin, and a combination thereof.

2. The multilayered cushion pad according to claim 1, wherein a part of the first woven fabric is overlapped with one part of the first buffering layer to form a first interface layer, and a part of the second woven fabric is overlapped with another part of the first buffering layer to form a second interface layer.

3. The multilayered cushion pad according to claim 2, wherein a thickness of the first interface layer ranges from 0.03 mm to 1.2 mm, and a thickness of the second interface layer ranges from 0.03 mm to 1.2 mm.

4. The multilayered cushion pad according to claim 1, wherein a basis weight of the first woven fabric ranges from 250 g/cm² to 800 g/cm², and a basis weight of the second woven fabric ranges from 250 g/cm² to 800 g/cm².

5. The multilayered cushion pad according to claim 1, wherein a basis weight of the multilayered cushion pad ranges from 1200 g/cm² to 1800 g/cm².

6. The multilayered cushion pad according to claim 1, wherein a total thickness of the multilayered cushion pad ranges from 25 mm to 45 mm.

7. The multilayered cushion pad according to claim 1, wherein a Shore hardness of the multilayered cushion pad ranges from 45 to 100.

8. The multilayered cushion pad according to claim 1, wherein a mechanical strength of the multilayered cushion pad ranges from 18 MPa to 30 MPa.

9. The multilayered cushion pad according to claim 1, wherein, when the multilayered cushion pad is disposed between a lower plate with a temperature of 30° C. and an upper plate with a temperature of 300° C., a heating rate of the multilayered cushion pad ranges from 15° C./minute to 25° C./minute.

10. The multilayered cushion pad according to claim 1, further comprising:
a third woven fabric disposed on the second woven fabric, a material of the third woven fabric being selected from the group consisting of: a poly-p-phenylene benzobisoxazole fiber, a polyphenylene sulfide fiber, a polybenzimidazole fiber, a ceramic fiber, a basalt fiber, an alkaline metal fiber, a silicic acid fiber, and a combination thereof; and
a second buffering layer disposed between the second woven fabric and the third woven fabric, a material of the second buffering layer being selected from the group consisting of: a silicone rubber resin, a fluororubber resin, a polyvinylidene difluoride resin, a polyetheretherketone resin, a polyimide resin, a polyamide-imide resin, and a combination thereof.

11. A method for manufacturing a multilayered cushion pad, comprising:
providing a first woven fabric and a second woven fabric, wherein a material of the first woven fabric includes a poly-p-phenylene benzobisoxazole fiber, and a material of the second woven fabric is selected from the group consisting of: a poly-p-phenylene benzobisoxazole fiber, a polyphenylene sulfide fiber, a polybenzimidazole fiber, a ceramic fiber, a basalt fiber, an alkaline metal fiber, a silicic acid fiber, and a combination thereof;
applying a first buffering resin between the first woven fabric and the second woven fabric to form a laminated structure, wherein the first buffering resin is selected from the group consisting of: a silicone rubber resin, a fluororubber resin, a polyvinylidene difluoride resin, a polyetheretherketone resin, a polyimide resin, a polyamide-imide resin, and a combination thereof; and
hot-pressing the laminated structure such that the first buffering resin is formed as a first buffering layer between the first woven fabric and the second woven fabric.

12. The method according to claim 11, wherein, in the step of hot-pressing the laminated structure, one part of the first buffering resin permeates into the first woven fabric and forms a first interface layer between the first woven fabric and the first buffering layer, and another part of the first buffering resin permeates into the second woven fabric and forms a second interface layer between the second woven fabric and the first buffering layer.
